(19) United States
(12) Patent Application Publication
(10) Pub. No.: US 2025/0385669 A1
(43) Pub. Date: Dec. 18, 2025

(54) SEMICONDUCTOR DEVICE

(71) Applicant: Mitsubishi Electric Corporation, Tokyo (JP)

(72) Inventor: Hiroki HIDAKA, Tokyo (JP)

(73) Assignee: Mitsubishi Electric Corporation, Tokyo (JP)

(21) Appl. No.: 19/044,541

(22) Filed: Feb. 3, 2025

(30) Foreign Application Priority Data
Jun. 14, 2024 (JP) 2024-096725

(51) Int. Cl. H03K 17/567; G11C 5/14; H01L 25/16; H10B 80/00; H10D 62/83; H10D 62/832; H10D 62/85

(52) U.S. Cl. CPC H03K 17/567; G11C 5/14; H01L 25/16; H10B 80/00; H10D 62/8303; H10D 62/8325; H10D 62/8503

(57) ABSTRACT

According to the present disclosure, a semiconductor device includes a plurality of semiconductor chips, an IC, a memory, and a plurality of terminals to be electrically connected to an outside, wherein the IC includes driving circuitry configured to drive the plurality of semiconductor chips and a plurality of switches connected to the plurality of terminals and configured to switch connection destinations of the plurality of terminals between the driving circuitry and the memory.

### BACKGROUND

### Field

The present disclosure relates to a semiconductor device.

### Background

JP 2019-57985 A discloses a semiconductor device including a semiconductor chip that is a power chip, an IC (integrated circuit) that controls driving of the semiconductor chip, a control signal terminal that receives a control signal for the semiconductor chip, a recording element, and a communication signal terminal for communicating with the recording element.

In the semiconductor device disclosed in JP 2019-57985 A, it is necessary to provide the communication signal terminal for communicating with the recording element. For this reason, it has been likely that miniaturization of the semiconductor device is hindered.

### SUMMARY

The present disclosure has been made in order to solve the problem described above, and an object of the present disclosure is to obtain a semiconductor device that can be miniaturized.

The features and advantages of the present disclosure may be summarized as follows.

According to an aspect of the present disclosure, a semiconductor device includes a plurality of semiconductor chips; an IC; a memory; and a plurality of terminals to be electrically connected to an outside, wherein the IC includes: driving circuitry configured to drive the plurality of semiconductor chips; and a plurality of switches connected to the plurality of terminals and configured to switch connection destinations of the plurality of terminals between the driving circuitry and the memory.

Other and further objects, features and advantages of the disclosure will appear more fully from the following description.

### BRIEF DESCRIPTION OF DRAWINGS

FIG. 1 is a circuit diagram of a semiconductor device according to a first embodiment.

FIG. 2 is a diagram illustrating a layout of the semiconductor device according to the first embodiment.

FIG. 3 is a circuit diagram of a semiconductor device according to a modification of the first embodiment.

FIG. 4 is a diagram illustrating a layout of the semiconductor device according to the modification of the first embodiment.

FIG. 5 is a circuit diagram of a semiconductor device according to a second embodiment.

FIG. 6 is a diagram illustrating a layout of the semiconductor device according to the second embodiment.

FIG. 7 is a circuit diagram of a semiconductor device according to a third embodiment.

FIG. 8 is a diagram illustrating a layout of the semiconductor device according to the third embodiment.

FIG. 9 is a circuit diagram of a semiconductor device according to a fourth embodiment.

FIG. 10 is a diagram illustrating a layout of a semiconductor device according to a fifth embodiment.

FIG. 11 is a circuit diagram of a semiconductor device according to a sixth embodiment.

FIG. 12 is a diagram illustrating a layout of the semiconductor device according to the sixth embodiment.

FIG. 13 is a plan view of a semiconductor device according to a seventh embodiment.

FIG. 14 is a diagram illustrating a state in which the semiconductor device according to the seventh embodiment is fixed to a substrate and a heat radiation fin.

### DESCRIPTION OF EMBODIMENTS

A semiconductor device according to each embodiment will be described with reference to the accompanying drawings. Components identical or corresponding to each other are indicated by the same reference characters, and repeated description of them is avoided in some cases.

### First Embodiment

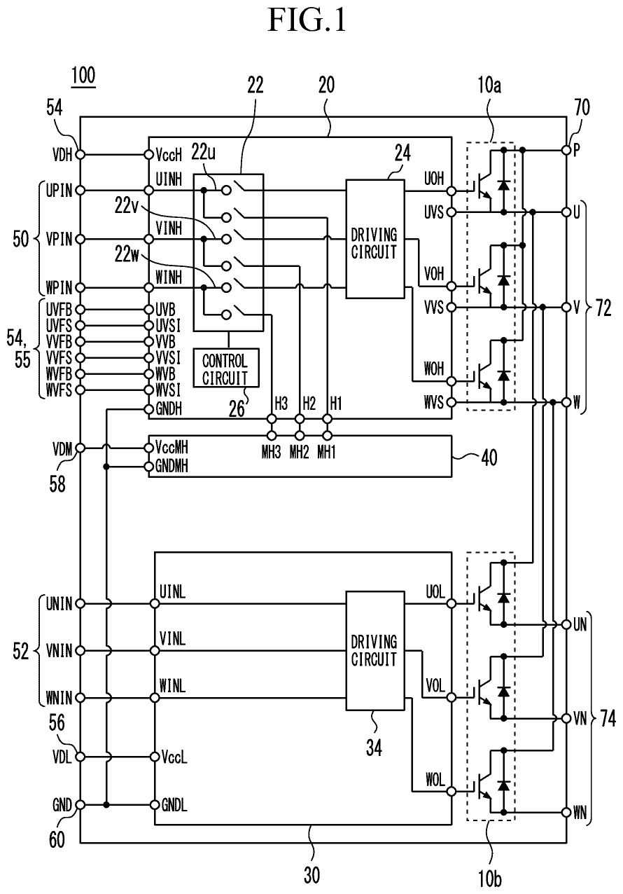

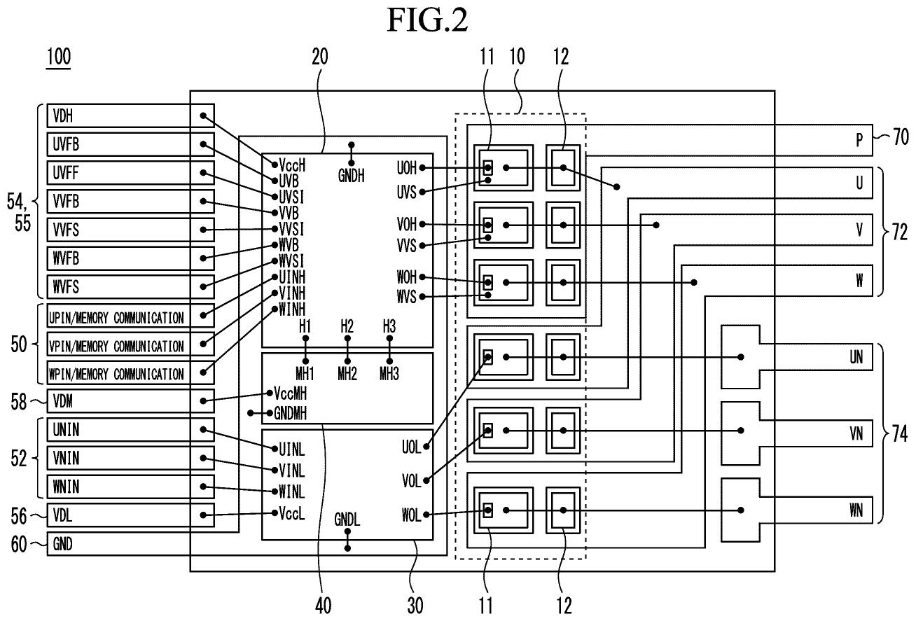

FIG. 1 is a circuit diagram of a semiconductor device 100 according to a first embodiment. FIG. 2 is a diagram illustrating a layout of the semiconductor device 100 according to the first embodiment. The semiconductor device 100 includes a high side on a P side and a low side on an N side. That is, the semiconductor device 100 includes, as a plurality of semiconductor chips 10, a plurality of semiconductor chips 10a on the high side and a plurality of semiconductor chips 10b on the low side. The semiconductor chips 10a and 10b are, for example, power chips. In the semiconductor device 100, semiconductor chips 10 corresponding to a U phase, a V phase, and a W phase are provided on each of the P side and the N side. The semiconductor device 100 is a semiconductor device called 6-in-1 or the like.

The semiconductor device 100 further includes an HVIC 20 configured to drive the plurality of semiconductor chips 10a on the high side and an LVIC 30 configured to drive the plurality of semiconductor chips 10b on the low side. Since ICs are divided into two ICs of an HVIC and an LVIC, wires connected to the semiconductor chips 10 from the ICs can be reduced in length. A circuit configuration of the semiconductor device 100 can be simplified. Note that the HVIC 20 and the LVIC 30 may be formed as a single IC. The semiconductor device 100 further includes a memory 40. The memory 40 is, for example, a nonvolatile recording element.

A P terminal is an output power supply terminal 70 for applying electric power to the semiconductor chips 10a and 10b. Output terminals 72 are outputs of the semiconductor chips 10a and 10b of the U phase, the V phase, and the W phase. The output terminals 72 include a U terminal corresponding to the outputs of the semiconductor chips 10a and 10b of the U phase, a V terminal corresponding to the outputs of the semiconductor chips 10a and 10b of the V phase, and a W terminal corresponding to the outputs of the semiconductor chips 10a and 10b of the W phase. Output reference potential terminals 74 are outputs of the semiconductor chips 10a and 10b of the U phase, the V phase, and the W phase. The output reference potential terminals 74 include a UN terminal corresponding to the U terminal, a VN terminal corresponding to the V terminal, and a WN terminal corresponding to the W terminal.

The semiconductor device 100 includes input signal terminals 50 and 52 for inputting, from the outside to the semiconductor device 100, input signals for controlling timing for driving the semiconductor chips 10a and 10b. The input signal terminals 50 on the P side are provided to correspond to the semiconductor chips 10a of the U phase, the V phase, and the W phase on the P side and include a UPIN terminal, a VPIN terminal, and a WPIN terminal for driving and controlling the semiconductor chips 10a. The input signal terminals 50 correspond to a plurality of terminals electrically connected to the outside and configured to receive input of input signals for driving the plurality of semiconductor chips 10a. Similarly, the input signal terminals 52 on the N side are provided to correspond to the semiconductor chips 10b of the U phase, the V phase, and the W phase on the N side and includes a UNIN terminal, a VNIN terminal, and a WNIN terminal for driving and controlling the semiconductor chips 10b.

The semiconductor device 100 includes control power supply terminals 54 and 56 for applying control electric power necessary for driving the semiconductor chips 10a and 10b. The control power supply terminals 54 include a VDH terminal for applying electric power to the HVIC 20 and a UVFB terminal, a VVFB terminal, and a WVFB terminal for respectively applying driving voltages to the semiconductor chips 10a of the U phase, the V phase, and the W phase on the P side. The control power supply terminal 56 includes a VDL terminal for applying electric power to the LVIC 30. The semiconductor device 100 includes control reference potential terminals 55 and 60 corresponding to the control power supply terminals 54 and 56. The control reference potential terminals 55 and 60 includes GND terminals corresponding to the VDH terminal and the VDL terminal, a UVFS terminal corresponding to the UVFB terminal, a VVFS terminal corresponding to the VVFB terminal, and a WVFS terminal corresponding to the WVFB terminal. A potential difference between a control power supply terminal and a control reference potential terminal corresponding to the control power supply terminal is defined as a control power supply voltage. For example, a driving voltage of the semiconductor chips 10a of the U phase on the P side, which is one of control power supply voltages, is a voltage obtained by subtracting the potential of the UVFS terminal from the potential of the UVFB terminal.

The semiconductor device 100 includes a VDM terminal that is a power supply terminal 58 that applies electric power to the memory 40. The VDM terminal and the GND terminal are connected to the memory 40. Further, the UPIN terminal, the VPIN terminal, and the WPIN terminal, which are the input signal terminals 50 on the P side, are connected to the memory 40 via a changeover switch 22 described below.

Subsequently, an internal configuration of the HVIC 20 is described. The HVIC 20 includes driving circuitry 24 configured to drive the plurality of semiconductor chips 10a. The driving circuitry 24 controls the plurality of semiconductor chips 10a according to signals input from the input signal terminals 50 via the changeover switch 22.

The changeover switch 22 includes a plurality of switches 22u, 22v, and 22w connected to the plurality of input signal terminals 50. The plurality of switches 22u, 22v, and 22w are provided to correspond to the plurality of input signal terminals 50. The plurality of switches 22u, 22v, and 22w are configured to switch connection destinations of the plurality of input signal terminals 50 between the driving circuitry 24 and the memory 40. The HVIC 20 includes control circuitry 26 configured to control the plurality of switches 22u, 22v, and 22w.

The changeover switch 22 can switch the connection destinations of the input signal terminals 50 between the driving circuitry 24 and the memory 40 according to any condition. Such control of the changeover switch 22 is executed by the control circuitry 26.

An internal configuration of the LVIC 30 is the same as the internal configuration of the HVIC 20 except that the changeover switch 22 and the control circuitry 26 are not provided. The LVIC 30 includes driving circuitry 34 configured to drive the plurality of semiconductor chips 10b. The driving circuitry 34 controls the plurality of semiconductor chips 10b according to signals input from the input signal terminals 52.

Subsequently, an example of a condition for switching the connection destinations of the input signal terminals 50 is described. The control circuitry 26 may switch the connection destinations of the input signal terminals 50 according to a control power supply voltage. In the following description, the control power supply voltage used for the switching of the connection destination by the changeover switch 22 is sometimes referred to as switching voltage. That is, the switching voltage only has to be a voltage of the control power supply terminals 54 and 56 configured to receive input of a control power supply voltage for driving any one of the plurality of semiconductor chips 10a and 10b. Specifically, a volage of the VDH terminal, the VDL terminal, the UVFB terminal, the VVFB terminal, or the WVFB terminal can be used as the switching voltage.

For example, the plurality of switches 22u, 22v, and 22w switch the connection destinations to the driving circuitry 24 when the switching voltage is equal to or higher than a predetermined first voltage and switch the connection destinations to the memory 40 when the switching voltage is lower than the first voltage. At this time, the control circuitry 26 reads the switching voltage and the first voltage determined in advance and stored in the control circuitry 26, the HVIC 20, the semiconductor device 100, or the like. The control circuitry 26 discriminates, according to a comparison result of the switching voltage and the first voltage, whether to switch the connection destinations to the memory 40 or the driving circuitry 24.

A second voltage lower than the first voltage may be stored in advance in the control circuitry 26, the HVIC 20, the semiconductor device 100, or the like. In this case, when the switching voltage is lower than the predetermined second voltage, data in the memory 40 is read from any one of the plurality of input signal terminals 50. When the switching voltage is lower than the first voltage and equal to or higher than the second voltage, data is written in the memory 40 from any one of the plurality of input signal terminals 50. In this way, the control circuitry 26 may switch a mode of the memory 40 between reading and writing according to a comparison result of the switching voltage and the second voltage.

For example, a case in which the first voltage is set to 5.0 V and the second voltage is set to 3.0 V is described. In this case, when the control power supply voltage is lower than 3.0 V, the plurality of switches 22u, 22v, and 22w are connected to the memory 40 and the memory 40 is switched to the reading mode. When the control power supply voltage is 3.0 to 5.0 V, the plurality of switches 22u, 22v, and 22w are connected to the memory 40 and the memory 40 is switched to the writing mode. When the control power supply voltage is equal to or higher than 5.0 V, the plurality of switches 22u, 22v, and 22w are connected to the driving circuitry 24.

The first voltage is desirably lower than a threshold voltage of the semiconductor chips 10a and 10b. In general, it is recommended that a semiconductor chip is used with control power set to approximately 15 V. For this reason, by setting the first and second voltages to, for example, 5.0 V and 3.0 V, lower than the threshold voltage, the connection destination of the changeover switch 22 is switched to the memory 40 at the time of the control power supply volage<5.0 V at which the semiconductor chips 10a and 10b are not driven. The connection destinations of the changeover switch 22 is switched to the driving circuitry 24 at the time of the control power supply voltage 5 V at which the semiconductor chips 10a and 10b are likely to be driven. Accordingly, in a state in which the driving of the semiconductor chips 10a and 10b is not assumed, the input signal terminals 50 can be used for reading or writing of the memory 40.

Note that the condition for switching the connection destinations of the input signal terminals 50 described above is an example. The connection destinations of the input signal terminals 50 may be switched according to any condition.

From the above, according to the present embodiment, by providing the changeover switch 22, it is possible to impart two functions to the plurality of input signal terminals 50. That is, it is possible to impart, to the input signal terminals 50, a function of controlling timing for driving the semiconductor chips 10a and a function of a communication terminal of the memory 40. Therefore, it is unnecessary to provide a terminal dedicated to communication with the memory 40. Therefore, it is possible to miniaturize the semiconductor device 100.

The switches 22u, 22v, and 22w of the U, V, and W phases in the present embodiment basically operate in association with one another. That is, states of the changeover switch 22 are only two states including a state in which all of the switches 22u, 22v, and 22w are connected to the driving circuitry 24 and a state in which all of the switches 22u, 22v, and 22w are connected to the memory 40.

On the other hand, in general, two terminals including a writing terminal and a reading terminal are necessary as communication terminals of a nonvolatile memory. For this reason, if at least two terminals among the input signal terminals 50 are connected to the memory 40, communication with the memory 40 is possible. Thus, as a modification of the present embodiment, there may be a state in which two of the input signal terminals 50 are connected to the memory 40 and one of the input signal terminals 50 is connected to the driving circuitry 24. For example, the U phase and the V phase may be connected to the memory 40 and the W phase may be connected to the driving circuitry 24.

Even in this case, there is no problem if a condition for switching the connection destinations of the changeover switch 22 to the memory 40 is a condition that the semiconductor chips 10a are not driven. That is, for example, even if the U phase and the V phase are connected to the memory 40 and only the W phase is connected to the driving circuitry 24, the semiconductor chip 10a of the W phase is not driven. Therefore, there is no problem even if only two input signal terminals 50 are connected to the memory 40.

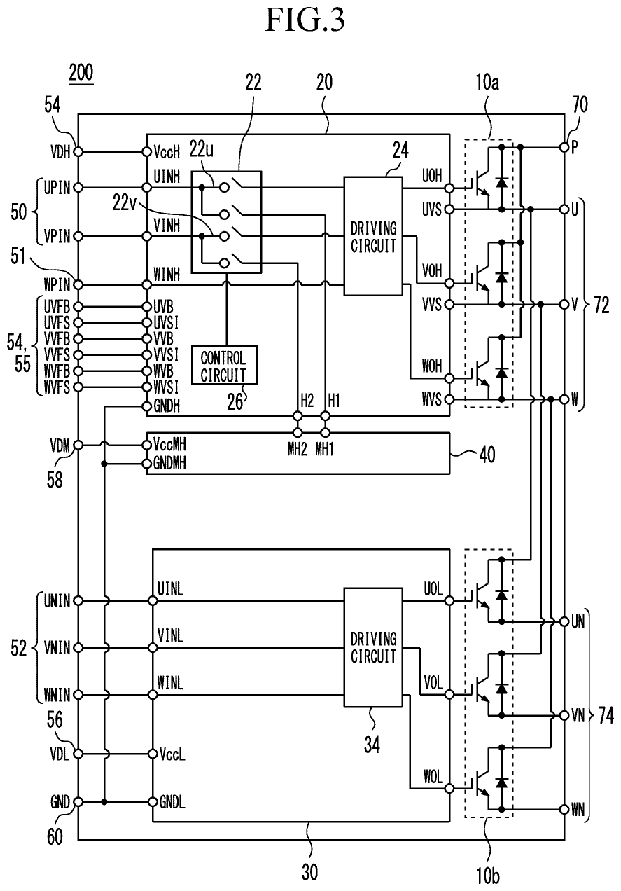

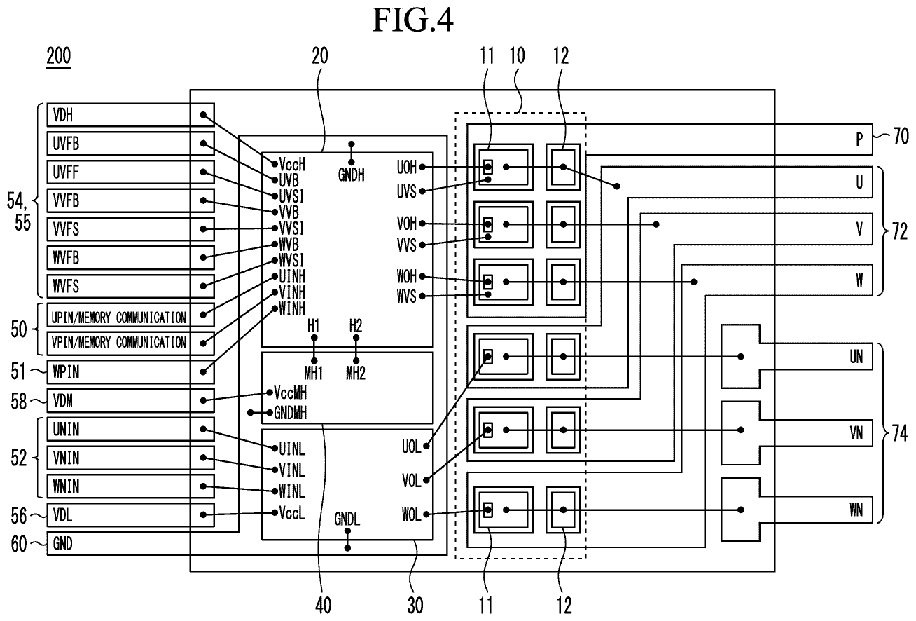

FIG. 3 is a circuit diagram of a semiconductor device 200 according to a modification of the first embodiment. FIG. 4 is a diagram illustrating a layout of the semiconductor device 200 according to the modification of the first embodiment. The changeover switch 22 may include only two switches 22u and 22v configured to switch the connection destinations of the input signal terminals 50 between the driving circuitry 24 and the memory 40. In the example illustrated in FIGS. 3 and 4, the switches 22u and 22v are provided in the U phase and the V phase and an input signal terminal 51 of the W phase is directly connected to the driving circuitry 24. As described above, even in such a configuration, there is no problem if the condition for switching the connection destination of the changeover switch 22 to the memory 40 is the condition that the semiconductor chips 10a are not driven.

Terminals connected to the changeover switch 22 are not limited to the input signal terminals 52. Another terminal provided in the semiconductor device 100 may be connected to the changeover switch 22 and a function of a communication terminal with the memory 40 may be imparted to the other terminal.

FIG. 2 illustrates an example in which, as the semiconductor chips 10 of the phases, IGBTs (insulated gate bipolar transistors) 11 and diodes 12 are provided as separate chips. Not only this, but the semiconductor chips 10 may be RC-IGBTs (reverse conducting IGBTs) in which IGBTs and diodes are provided as the same chips. Note that all semiconductor chips driven by an IC can be adopted as the semiconductor chips 10.

A configuration of the semiconductor device 100 is not limited to the configuration described in the present embodiment. As the semiconductor device 100, all semiconductor devices including a semiconductor chip, an IC that drives the semiconductor chip, and a memory can be adopted.

The semiconductor chip 10 may be made with a wide band gap semiconductor. The wide band gap semiconductor is a silicon carbide, a gallium nitride-based material, or diamond. A switching device or a diode formed by the wide band gap semiconductor has a high withstand voltage property and also has a high allowable current density. Therefore, it is possible to further miniaturize the semiconductor device 100.

Functions of the changeover switch 22, the driving circuitry 24, and the control circuitry 26 can be implemented by one or a plurality of arithmetic devices. The arithmetic devices may be dedicated hardware. The arithmetic device may be a CPU (Central Processing Unit) that executes a program stored in a memory. The CPU may be a central processing device, a processing device, a microprocessor, a microcomputer, a processor, or a DSP (Digital Signal Processor). Note that the memory in which the program is stored may be the memory 40 or may be provided separately from the memory 40.

When the arithmetic device is the dedicated hardware, the arithmetic device may be, for example, a single circuit, a composite circuit, a programmed processor, or a parallel-programed processor. The arithmetic device may be an ASIC (Application Specific Integrated Circuit) or an FPGA (Field-Programmable Gate Array). Further, the arithmetic device may be a combination of these devices. The respective functions of the units of the changeover switch 22, the driving circuitry 24, and the control circuitry 26 may be implemented by separate arithmetic devices. The functions of the units may be collectively implemented by one arithmetic device.

When the arithmetic device is the CPU, the functions of the changeover switch 22, the driving circuitry 24, and the control circuitry 26 are implemented by software, firmware, or a combination of the software and the firmware. The software and the firmware are described as a program and stored in a memory. The arithmetic device reads and executes the program stored in the memory to thereby implement the functions of the units.

That is, a program for switching the connection destinations of the plurality of input signal terminals 50 between the driving circuitry 24 and the memory 40, a program for driving the plurality of semiconductor chips 10a, and a program for communicating with the memory 40 are stored in the memory. These programs are also considered to be programs for causing a computer to execute procedures or methods in the changeover switch 22, the driving circuitry 24, and the control circuitry 26.

Here, the memory in which the programs are stored may be a nonvolatile or volatile semiconductor memory such as a RAM, a ROM, a flash memory, an EPROM, or an EEPROM. The memory may be a magnetic disk, a flexible disk, an optical disk, a compact disc, a minidisc, a DVD, or the like. RAM is an abbreviation of Random Access Memory. ROM is an abbreviation of Read Only Memory. EPROM is an abbreviation of Erasable Programmable Read Only Memory. EEPROM is an abbreviation of Electrically Erasable Programmable Read-Only Memory. A plurality of memories may be provided.

Note that, concerning the functions of the changeover switch 22, the driving circuitry 24, and the control circuitry 26, a part may be implemented by dedicated hardware and a part may be implemented by software or firmware. In this way, the arithmetic device can implement the functions described above with hardware, software, firmware, or a combination of the hardware, the software, and the firmware.

These modifications can be appropriately applied to semiconductor devices according to embodiments below. Meanwhile, for the semiconductor devices according to the embodiments below, dissimilarities with the first embodiment will mainly be explained as they have many similarities with the first embodiment.

### Second Embodiment

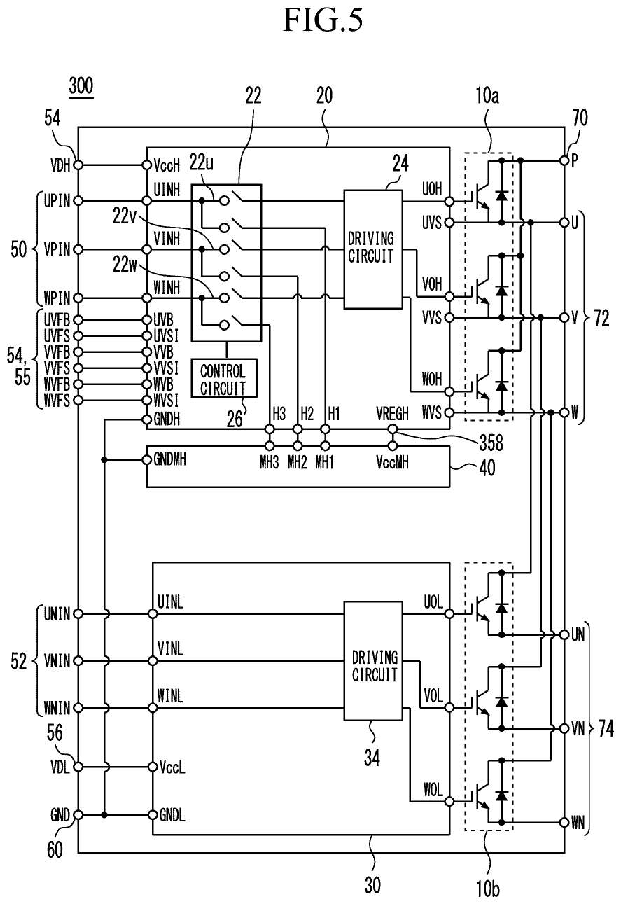

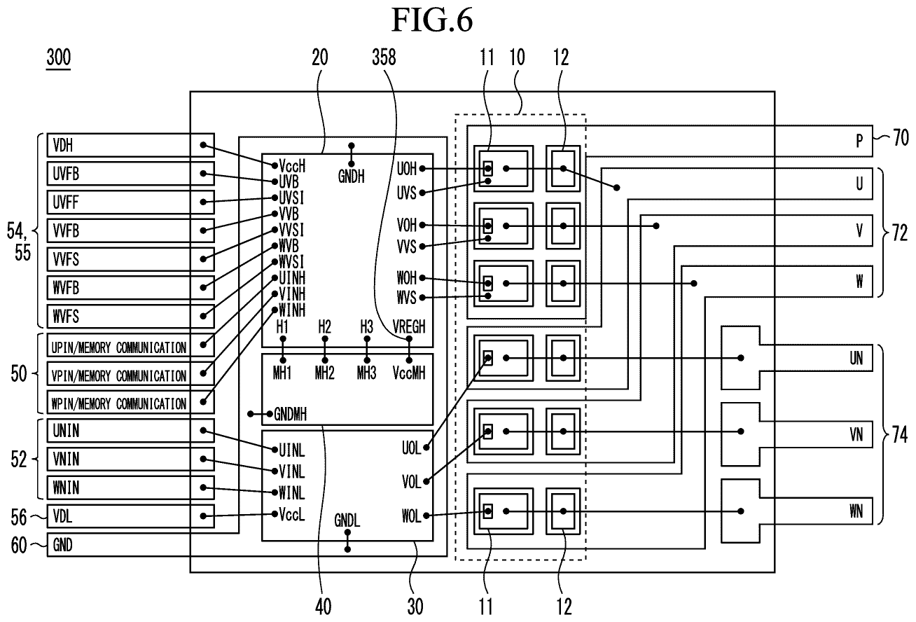

FIG. 5 is a circuit diagram of a semiconductor device 300 according to a second embodiment. FIG. 6 is a diagram illustrating a layout of the semiconductor device 300 according to the second embodiment. The present embodiment is different from the first embodiment in that the memory 40 is configured to receive power supply from the HVIC 20. The other components are the same as the components in the first embodiment.

The HVIC 20 includes a VRGH terminal that is an IC internal power supply terminal 358. The memory 40 receives power supply from an internal power supply of the HVIC 20 via the IC internal power supply terminal 358. This makes the power supply terminal 58 of the memory 40 unnecessary. It is possible to mount the memory 40 while keeping an existing terminal configuration. It is possible to further miniaturize the semiconductor device 300.

### Third Embodiment

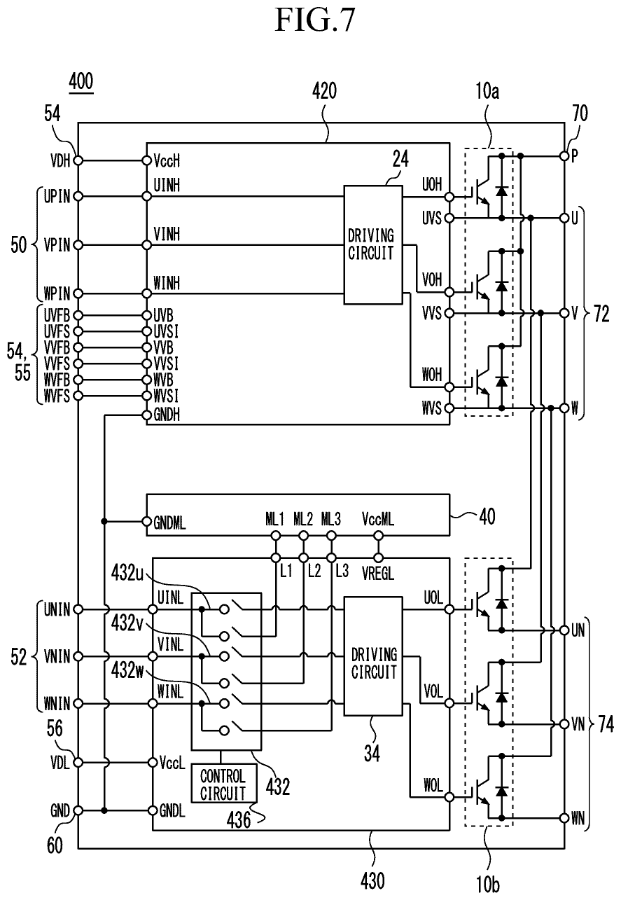

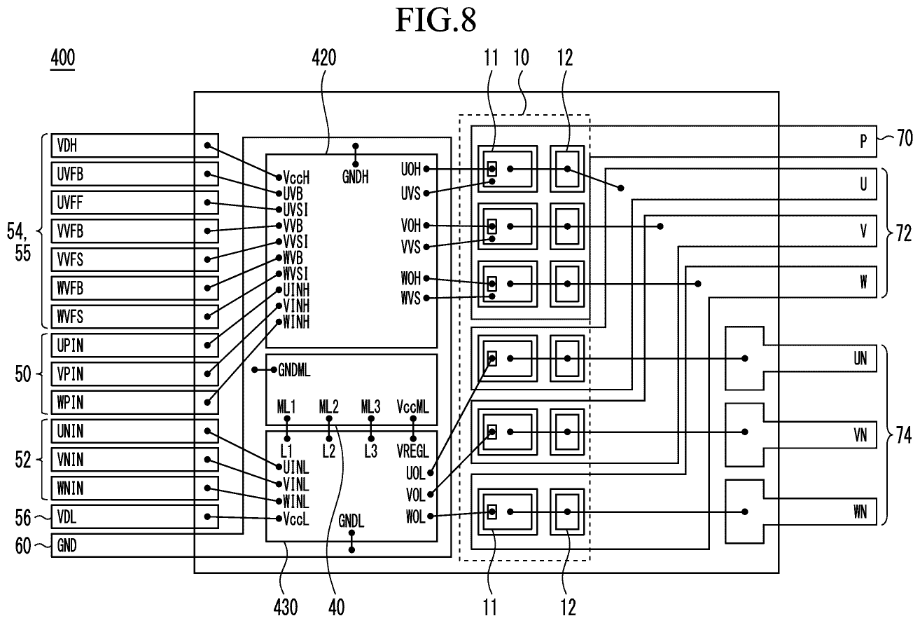

FIG. 7 is a circuit diagram of a semiconductor device 400 according to a third embodiment. FIG. 8 is a diagram illustrating a layout of the semiconductor device 400 according to the third embodiment. The present embodiment is different from the first embodiment in that a changeover switch 432 is mounted on an LVIC 430.

The changeover switch 432 includes a plurality of switches 432u, 432v, and 432w connected to the plurality of input signal terminals 52. The plurality of switches 432u, 432v, and 432w are provided to correspond to the plurality of input signal terminals 52. The plurality of switches 432u, 432v, and 432w are configured to switch the connection destinations of the plurality of input signal terminals 52 between the driving circuitry 34 and the memory 40. The LVIC 430 includes control circuitry 436 configured to control the plurality of switches 432u, 432v, and 432w.

The changeover switch 432 can switch the connection destinations of the input signal terminals 52 between the driving circuitry 34 and the memory 40 according to any condition. Such control of the changeover switch 432 is executed by the control circuitry 436. As the condition for switching the changeover switch 432, the same condition as the condition in the first embodiment can be adopted. In the present embodiment as well, the memory 40 may receive power supply from the LVIC 430.

An internal configuration of the HVIC 420 is the same as the internal configuration of the HVIC 20 except that the changeover switch 22 and the control circuitry 26 are not provided.

As described above, an IC mounted with a changeover switch may be one of an HVIC and an LVIC. Note that, in the present embodiment as well, at least two terminals among the input signal terminals 52 only have to be connected to the memory 40 via a switch.

### Fourth Embodiment

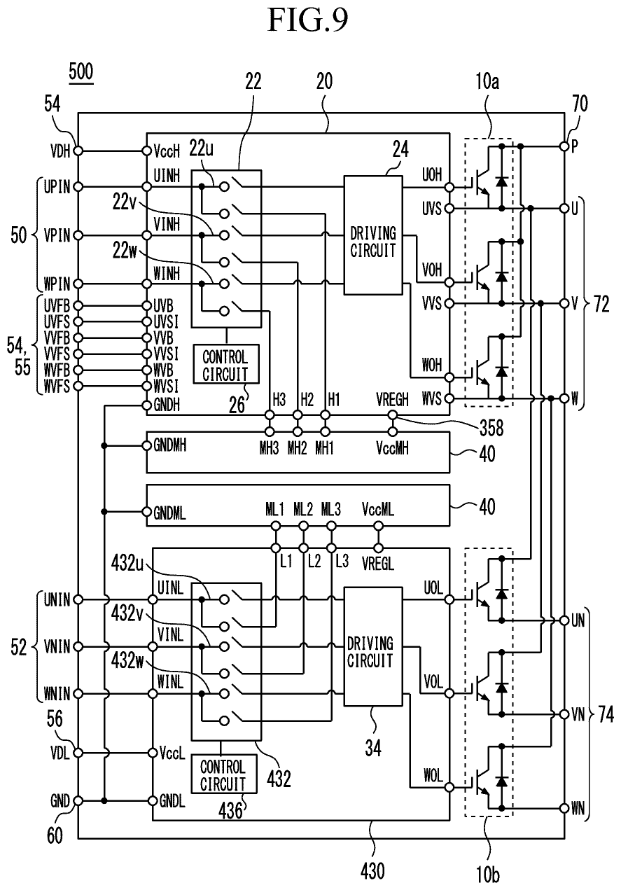

FIG. 9 is a circuit diagram of a semiconductor device 500 according to a fourth embodiment. The present embodiment is different from the first embodiment in that the changeover switches 22 and 432 are mounted on both of the HVIC 20 and the LVIC 430. The semiconductor device 500 includes two memories 40. The memories 40 are respectively connected to the HVIC 20 and the LVIC 430.

The changeover switch 22 of the HVIC 20 and the changeover switch 432 of the LVIC 430 operate in association with each other. That is, all of the switches 22u, 22v, 22w, 432u, 432v, and 432w are connected to the driving circuitry 24 and 34 or connected to the memories 40. Note that, in the present embodiment as well, at least two terminals among the input signal terminals 50 only have to be connected to the memory 40 via a switch and at least two terminals among the input signal terminals 52 only have to be connected to the memory 40 via a switch.

One memory 40 common to the HVIC 20 and the LVIC 430 may be provided. In the present embodiment as well, the memory 40 may receive power supply from an IC corresponding to the memory 40.

### Fifth Embodiment

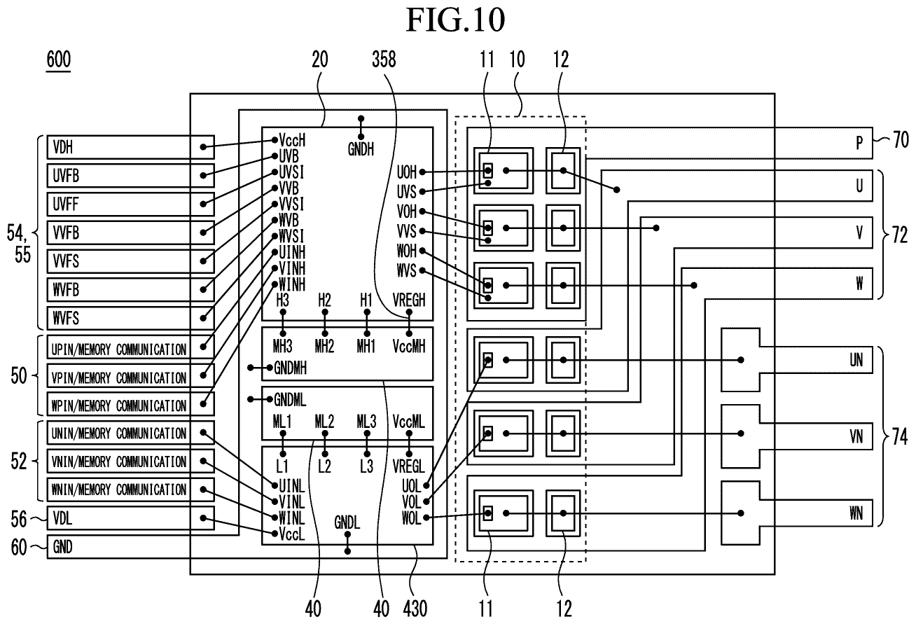

FIG. 10 is a diagram illustrating a layout of a semiconductor device 600 according to a fifth embodiment. A plurality of memories 40 may be located between the HVIC 20 and the LVIC 430. The same applies when one memory 40 is provided as in the first to third embodiments.

When a terminal connected to the HVIC 20 or a terminal connected to the LVIC 430 is also used as a communication terminal of the memory 40, the position of the memory 40 is optimally a position between the HVIC 20 and the LVIC 430. Accordingly, it is possible to further miniaturize the semiconductor device 600.

### Sixth Embodiment

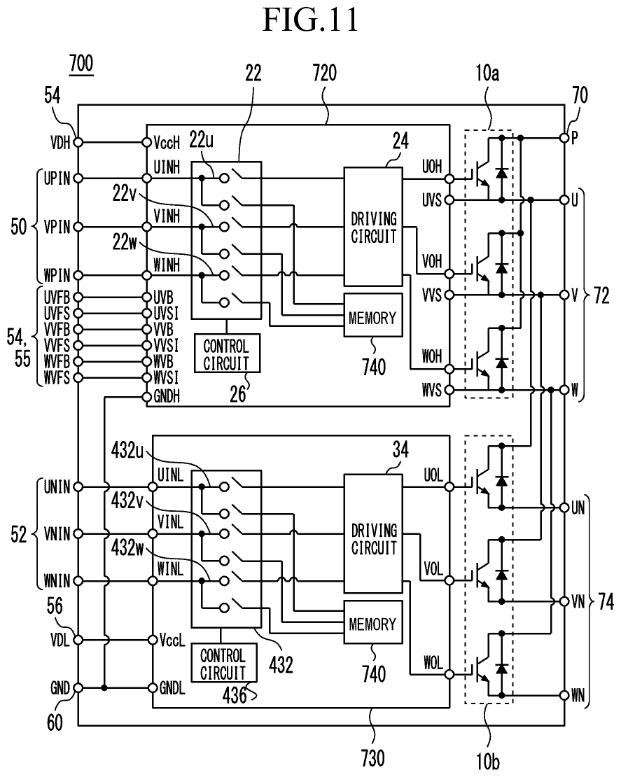

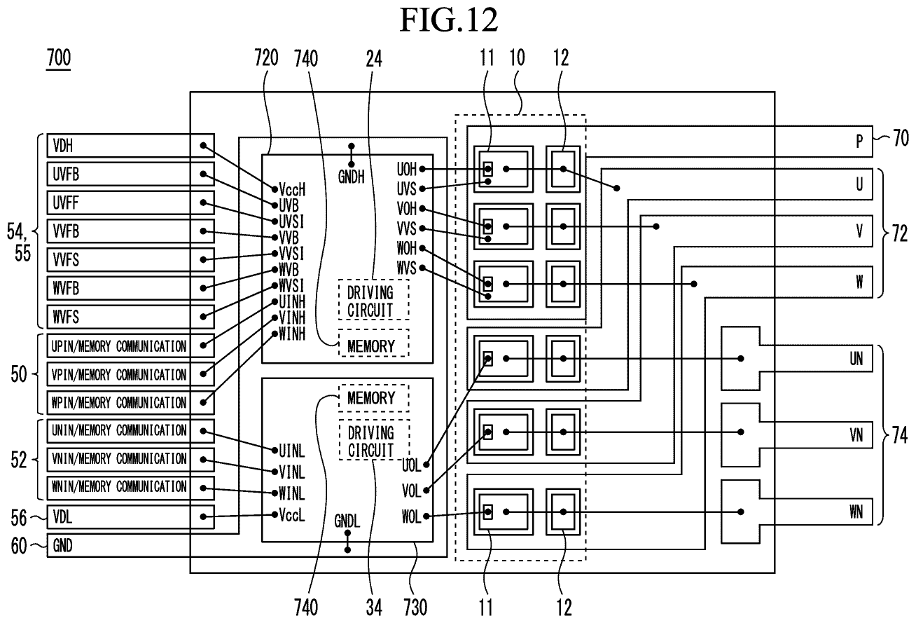

FIG. 11 is a circuit diagram of a semiconductor device 700 according to a sixth embodiment. FIG. 12 is a diagram illustrating a layout of the semiconductor device 700 according to the sixth embodiment. The present embodiment is different from the fourth embodiment in that memories 740 are incorporated in an HVIC 720 and an LVIC 730. A configuration of the HVIC 720 and the LVIC 730 is the same as the configuration of the HVIC 20 and the LVIC 430 except that the memories 740 are incorporated in the HVIC 720 and the LVIC 730. Accordingly, it is possible to further miniaturize the semiconductor device 700.

Note that, in the first to third embodiments as well, the memory 40 may be incorporated in an IC corresponding to the memory 40.

### Seventh Embodiment

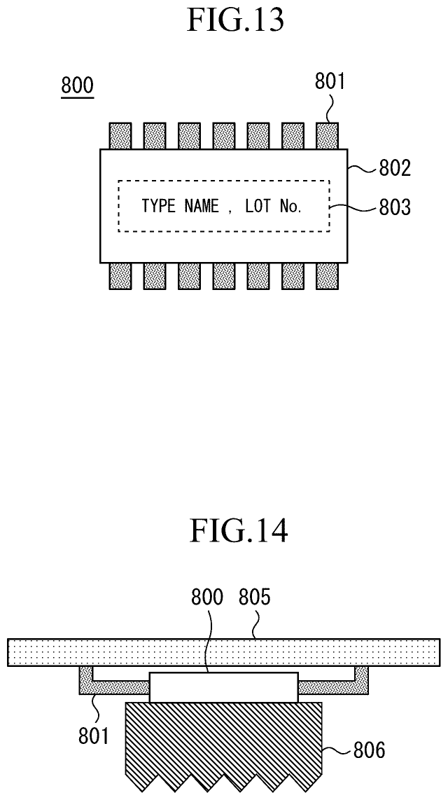

FIG. 13 is a plan view of a semiconductor device 800 according to a seventh embodiment. FIG. 14 is a diagram illustrating a state in which the semiconductor device 800 according to the seventh embodiment is fixed to a substrate 805 and a heat radiation fin 806. The semiconductor device 800 includes, on the rear surface of a package 802, a printed portion 803 on which a product model name and lot information are described. Terminals 801 are provided on both sides of the package 802. The terminals 801 are terminals of the semiconductor device 100 illustrated in FIG. 2 and the like.

The semiconductor device 800 is attached to the substrate 805 and the heat radiation fin 806 and used in an actual use environment. At this time, the printed portion 803 is sometimes provided on the rear surface of a package to which the substrate 805 or the heat radiation fin 806 adheres. For this reason, to check the product model name or the lot information of the semiconductor device 800 in the actual use environment, it is necessary to detach the semiconductor device 800 from the substrate 805 or the heat radiation fin 806 and check the printed portion 803. However, the substrate 805 and the heat radiation fin 806 are often fixed by screwing or soldering. Therefore, it is not easy to detach the substrate 805 and the heat radiation fin 806. For this reason, there has been a problem in that the product model name and the lot information cannot be easily checked in the actual use environment.

On the other hand, the memory 40 in the present embodiment records product information of the semiconductor device 800. The product information is a product model name, lot information, final inspection data before shipment, and the like. The product information may be any one of the product model name, the lot information, the final inspection data before shipment, and the like or a combination thereof. Accordingly, it is possible to check the product information of the semiconductor device 800 from the input signal terminals 50 or the input signal terminals 52. For this reason, it is unnecessary to detach the semiconductor device 800 from the substrate 805 or the heat radiation fin 806. Therefore, it is possible to easily check the production information in the actual use environment of the semiconductor device 800. It is possible to optionally check the product information at a customer's place and improve convenience of the semiconductor device 800.

Meanwhile, technical features explained in each embodiment may be appropriately combined to use.

Hereinafter, various aspects of the present disclosure will be collectively described as appendixes.

### Appendix 1

A semiconductor device comprising:
a plurality of semiconductor chips;
an IC;
a memory; and
a plurality of terminals to be electrically connected to an outside, wherein
the IC includes:
   driving circuitry configured to drive the plurality of semiconductor chips; and
   a plurality of switches connected to the plurality of terminals and configured to switch connection destinations of the plurality of terminals between the driving circuitry and the memory.

### Appendix 2

The semiconductor device according to appendix 1, wherein the plurality of terminals are configured to receive input of input signals for driving the plurality of semiconductor chips.

### Appendix 3

The semiconductor device according to appendix 1 or 2, wherein the IC includes control circuitry configured to control the plurality of switches.

### Appendix 4

The semiconductor device according to any one of appendixes 1 to 3, further comprising
a control power supply terminal configured to receive input of a control power supply voltage for driving any one of the plurality of semiconductor chips, wherein
the plurality of switches switch the connection destinations to the driving circuitry when a voltage of the control power supply terminal is equal to or higher than a predetermined first voltage and switch the connection destinations to the memory when the voltage of the control power supply terminal is lower than the first voltage.

### Appendix 5

The semiconductor device according to appendix 4, wherein the first voltage is lower than a threshold voltage of the semiconductor chips.

### Appendix 6

The semiconductor device according to appendix 4 or 5, wherein
when the voltage of the control power supply terminal is lower than a predetermined second voltage lower than the first voltage, data in the memory is read from any one of the plurality of terminals, and
when the voltage of the control power supply terminal is lower than the first voltage and equal to or higher than the second voltage, data is written in the memory from any one of the plurality of terminals.

### Appendix 7

The semiconductor device according to any one of appendixes 1 to 6, wherein the memory is configured to receive power supply from the IC.

### Appendix 8

The semiconductor device according to any one of appendixes 1 to 7, further comprising:
a plurality of semiconductor chips on a high side;
a plurality of semiconductor chips on a low side;
an HVIC configured to drive the plurality of semiconductor chips on the high side; and
an LVIC configured to drive the plurality of semiconductor chips on the low side, wherein
the IC is one of the HVIC and the LVIC.

### Appendix 9

The semiconductor device according to any one of appendixes 1 to 7, further comprising:
the plurality of semiconductor chips on a high side;
the plurality of semiconductor chips on a low side;
an HVIC provided as the IC on the high side; and
an LVIC provided as the IC on the low side.

### Appendix 10

The semiconductor device according to appendix 8 or 9, wherein the memory is located between the HVIC and the LVIC.

### Appendix 11

The semiconductor device according to any one of appendixes 1 to 9, wherein the memory is incorporated in the IC.

### Appendix 12

The semiconductor device according to any one of appendixes 1 to 11, wherein the memory records product information of the semiconductor device.

### Appendix 13

The semiconductor device according to any one of appendixes 1 to 12, wherein the semiconductor chips are made with a wide band gap semiconductor.

### Appendix 14

The semiconductor device according to claim 13, wherein the wide band gap semiconductor is silicon carbide, gallium-nitride-based material or diamond.

In the semiconductor device according to the present disclosure, since the plurality of switches are provided, it is possible to impart two functions to the plurality of terminals. Therefore, it is possible to miniaturize the semiconductor device.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-096725, filed on Jun. 14, 2024 including specification, claims, drawings and summary, on which the Convention priority of the present application is based, are incorporated herein by reference in its entirety.

1. A semiconductor device comprising:
a plurality of semiconductor chips;
an IC;
a memory; and
a plurality of terminals to be electrically connected to an outside, wherein
the IC includes:
driving circuitry configured to drive the plurality of semiconductor chips; and
a plurality of switches connected to the plurality of terminals and configured to switch connection destinations of the plurality of terminals between the driving circuitry and the memory.

2. The semiconductor device according to claim 1, wherein the plurality of terminals are configured to receive input of input signals for driving the plurality of semiconductor chips.

3. The semiconductor device according to claim 1, wherein the IC includes control circuitry configured to control the plurality of switches.

4. The semiconductor device according to claim 1, further comprising a control power supply terminal configured to receive input of a control power supply voltage for driving any one of the plurality of semiconductor chips, wherein
the plurality of switches switch the connection destinations to the driving circuitry when a voltage of the control power supply terminal is equal to or higher than a predetermined first voltage and switch the connection destinations to the memory when the voltage of the control power supply terminal is lower than the first voltage.

5. The semiconductor device according to claim 4, wherein the first voltage is lower than a threshold voltage of the semiconductor chips.

6. The semiconductor device according to claim 4, wherein
when the voltage of the control power supply terminal is lower than a predetermined second voltage lower than the first voltage, data in the memory is read from any one of the plurality of terminals, and
when the voltage of the control power supply terminal is lower than the first voltage and equal to or higher than the second voltage, data is written in the memory from any one of the plurality of terminals.

7. The semiconductor device according to claim 1, wherein the memory is configured to receive power supply from the IC.

8. The semiconductor device according to claim 1, further comprising:
a plurality of semiconductor chips on a high side;
a plurality of semiconductor chips on a low side;
an HVIC configured to drive the plurality of semiconductor chips on the high side; and
an LVIC configured to drive the plurality of semiconductor chips on the low side, wherein
the IC is one of the HVIC and the LVIC.

9. The semiconductor device according to claim 1, further comprising:
the plurality of semiconductor chips on a high side;
the plurality of semiconductor chips on a low side;
an HVIC provided as the IC on the high side; and
an LVIC provided as the IC on the low side.

10. The semiconductor device according to claim 8, wherein the memory is located between the HVIC and the LVIC.

11. The semiconductor device according to claim 9, wherein the memory is located between the HVIC and the LVIC.

12. The semiconductor device according to claim 1, wherein the memory is incorporated in the IC.

13. The semiconductor device according to claim 1, wherein the memory records product information of the semiconductor device.

14. The semiconductor device according to claim 1, wherein the semiconductor chips are made with a wide band gap semiconductor.

15. The semiconductor device according to claim 14, wherein the wide band gap semiconductor is silicon carbide, gallium-nitride-based material or diamond.
